(19) United States
(12) Patent Application Publication
(10) Pub. No.: US 2006/0237855 A1
(43) Pub. Date: Oct. 26, 2006

(54) Substrate for producing a soldering connection to a second substrate

(76) Inventors: Steffen Kroehnert, Dresden (DE); Gunnar Petzold, Dresden (DE); Jens Oswald, Dresden (DE); Martin Reiss, Dresden (DE); Oliver Grassme, Dresden (DE); Kerstin Nocke, Dresden (DE); Knut Kahlisch, Dresden (DE); Soo Gil Park, Radebeul (DE)

Correspondence Address: SLATER & MATSIL LLP, 17950 PRESTON ROAD, SUITE 1000, DALLAS, TX, 75252, US

(21) Appl. No.: 11/392,255

(22) Filed: Mar. 29, 2006

(30) Foreign Application Priority Data
Mar. 29, 2005 (DE) 10 2005 014 665.1

(51) Int. Cl. H01L 23/48; H01L 23/52; H01L 29/40

(52) U.S. Cl. 257/779; 257/781

(57) ABSTRACT

A substrate for producing a soldering connection to a second substrate is disclosed. Soldering pads are distributed on the substrate surface. Solder balls can be applied to these pads. A soldering pad has a top side area and side areas connected to a conductor track. A soldering mask with openings in the region of the soldering pads is applied to the substrate. A soldering pad is provided with holding mechanism for the solder balls in such a way that, within the top side area of the soldering pad, a depression is introduced in the direction of the substrate or an elevation rising above the top side area is applied.

This application claims priority to German Patent Application 10 2005 015 665.1, which was filed Mar. 29, 2005, and is incorporated herein by reference.

### TECHNICAL FIELD

The invention relates to electronic components and in specific embodiments to a substrate for producing a soldering connection to a second substrate.

### BACKGROUND

Substrates of this type serve for the mounting and electrical connection of semiconductor chips. The semiconductor chips are fixed on the substrate and connected to conductor tracks that lead to soldering pads. This connection, for its part, may be effected by means of a soldering connection between contact pads on the semiconductor chip and corresponding contact pads at the conductor tracks. However, the connection may also be realized by a wire connection between the corresponding contact pads on semiconductor chip and substrate. The substrate is provided with solder balls on its soldering pads. A semiconductor component produced in this way then serves for further mounting, in which case it is soldered onto a second substrate, for example a printed circuit board, by means of the solder balls. The arrangement of the soldering pads distributed on the substrate surface is also referred to as “ball grid array.”

The soldering connections between the substrate and the second substrate are exposed to a particular mechanical stress brought about by a thermal cyclic loading or by mechanical loading. The thermally generated stress loading is intensified by the fact that materials having different coefficients of thermal expansion are joined together with the soldering connection. The different thermal expansion brought about as a result of this effects, particularly on the part of the semiconductor component, on the soldering connections a normal and shear loading that often leads to the breakaway of the connection, thus disturbing the function of the semiconductor component. The breakaway usually takes place between the soldering pad and the solder of the solder ball.

The soldering connections of ball grid arrays, the soldering connections being arranged in matrix-like fashion in a grid, are exposed to particular stress action on account of the planar extent. This is critical principally for asymmetrical ball arrangements, because stress maxima arise locally. As early as during the soldering process the substrates and components may be subjected to a warpage, which may lead to a deformation of the solder balls in the z direction, that is to say perpendicular to the substrate, and also to latent stress states within the solder balls. The different expansions also cause shear forces to arise in the x and y directions, that is to say parallel to the substrate.

The reliability of the soldering connections thus deteriorates particularly when such stress factors occur simultaneously.

It is known to provide the substrate surface with a soldering resist. The properties of soldering resist, which is applied in planar fashion on most substrates or the printed circuit boards after metallization and prior to producing the soldering connections, in order to prevent solder that flows out during soldering from forming electrically conductive bridges to adjacent conduction structures or to adjacent soldering pads, and in order to improve the electrical properties of the printed circuit boards and substrates, in particular to increase the flashover strength, likewise influences the reliability of the soldering connection, however.

The soldering resist is a polymer that is not wetted by the solder during the soldering operation. Application takes place usually by means of screen printing technology or by means of phototechnology, screen printing being used increasingly less often, because the fit tolerance that can be achieved thereby is insufficient for many applications. In the course of applying the soldering resist, the soldering pads and likewise holes and slots remain free of resist or are uncovered again by means of suitable methods, with the result that the soldering resist patterned in this way forms a mask.

It is, therefore, known to use the soldering resist for shaping the solder balls as well. A ball grid array (BGA) whose solder balls are influenced by the soldering resist is usually referred to as SMD-BGA (SMD=Solder Mask Defined). In this case, a layer of the soldering resist is patterned to form a soldering mask such that openings that are free of soldering resist arise above the soldering pads. In the case of the SMD-BGA, the diameters of the openings are then less than the diameters of the soldering pads. Since the openings lie centrally with respect to the soldering pads given proper positioning, the edge of the soldering pads is covered by the soldering resist. This brings about first of all an additional mechanical stability of the soldering pad, since the edge thereof experiences an additional support. Moreover, the solder ball is shaped by the opening in the soldering mask. This has the advantage of avoiding incorrect contact-connections of conductor tracks, which are adjacent to the soldering pad. However, the solder balls are thus seated only on the surface of the soldering pad. This means that forces acting on the solder ball may easily lead to the breakaway thereof.

The SMD configuration is employed particularly in the case of relatively dense ball grids and relatively dense conduction structures. Since the open, resist-free regions of the soldering resist mask are configured to be smaller than the soldering pads situated underneath, it is necessary to develop precise soldering resist edges since just a little coverage of the soldering pad with soldering resist has the effect that a veil that forms coats the entire area and causes soldering faults. Moreover, it has been ascertained that the periphery sharp edge of the soldering resist has a notch effect on the soldering connection, thus giving rise to a weakening of the connection and to the interruption of the soldering connection even at relatively low normal and shear stresses. U.S. Pat. No. 6,228,466 B1, which is incorporated herein by reference, illustrates such soldering pads with periphery coverage of the soldering pad edge by a resist mask for ball grid array contacts.

The '466 patent likewise describes the embodiment of a contact of a wiring on a substrate, in which a resist mask covers the wiring excluding those regions that serve for producing the soldering contact, the resist mask being pulled back completely from the surface of the contact region of the wiring apart from individual, small edge regions. In order to improve the adhesion of the contact regions on the substrate surface, however, the resist mask is pulled back only to an extent such that a connection between the resist mask and the periphery side areas of the contact region is present over the entire periphery. It is only in individual sections of the periphery that the resist surface is lowered below the surface of the contact region and this fraction of the side area is thus uncovered for participation in the soldering connection.

What is disadvantageous in this case, however, is that the production of this particular topography of the resist mask in the vicinity of the contact region requires particularly complicated and cost-intensive methods and, depending on the method, possibly also additional transport and positioning sequences. Furthermore, the adhesive improvement that can be achieved thereby is not sufficient for soldering connections with stress loads such as occur particularly in the integration of BGA packages.

An embodiment of contact pads for soldering connections arranged in grid like fashion is described in Japanese Patent No. 2001-230513 A, wherein the areas of the pad and of the corresponding mask opening are displaced relative to one another so that a part of the pad is covered by the mask and, on account of this, this mask region projects into the solder ball and at the same time uncovers a part of the side area of the pad, whereby this part is included in the soldering connection. The Japanese patent is incorporated herein by reference. In order to obtain a sufficient coverage that withstands the tensile and shear loading to a sufficient degree, the soldering pads are always made larger than is absolutely necessary for the connection. What is disadvantageous in this case, however, is that an enlargement of the soldering pads is appropriate either only in the edge region of the grid or in isolated fashion on account of the ever decreasing grid dimensions and the ever more demanding grid geometries.

Another configuration can be seen in NSMD-BGA (NSMD=Non Solder Mask Defined). In this case, the solder balls are not defined by the soldering mask, e.g., by virtue of the diameter of the opening in the soldering mask being larger than the soldering pad. This means that the edge of the soldering pad is not covered by soldering resist. On the one hand, this affords the advantage that the solder ball can also reach laterally around the soldering pad. This is because the soldering pad normally projects above the rest of the substrate surface to the height of its layer thickness. This reaching around laterally brings about an additional positively locking connection between the solder ball and the soldering pad. However, in NSMD configurations there is always the risk that by means of the solder ball itself or by means of the soldering operation during mounting solder will then pass to adjacent conductor tracks and incorrect contact-connections will consequently occur.

Particularly in the case of insufficient fit tolerance of the soldering resist mask, on account of the possible non-central arrangement of soldering pad and resist-free region there is the risk of soldering bridge formation between soldering pad and adjacent conductor track, since the minimum electrical distance between soldering pad and conductor track is not complied with or the solder even covers a part of the conductor track. If a part of the soldering pad is covered by soldering resist on account of non-central arrangement or insufficient fit tolerance, a thin, transparent veil may arise on the soldering pad and leads to soldering faults during soldering.

This last is often combated in practice by configuring the resist-free regions to be significantly larger than would be necessary in accordance with the soldering pad size. Besides the possible formation of short-circuiting bridges, this additionally leads to the reduction in size of the webs remaining between the resist-free regions and thus of the adhesion area present for the adhesion of the soldering resist mask on the printed circuit board or the substrate. On account of this, during the subsequent production process, excessively narrow webs of the soldering resist mask may detach from the substrate and cause soldering bridges.

Such soldering pads with a soldering resist mask pulled back relatively far have a further soldering location defect, which is typical of ball grid arrays and is caused by cracking at the interface of the substrate in the region beneath the soldering pad. Under the mechanical loading described, the cracking practically leads to the peeling away of the soldering pads including a superficial layer of the substrate and to the destruction of the conduction structure into which the soldering pad is integrated.

The pulling back of the soldering resist mask is additionally limited by the grid dimension of the soldering connections of the ball grid arrays and by the density of the conduction structures on the printed circuit board, since it is necessary to comply with the required electrical distance in order to ensure the flashover strength and the resist-free regions around a soldering pad are also not permitted to uncover an adjacent conductor track in order to avoid solder bridge formation.

In order to improve the stress resistance it is appropriate to change from an SMD configuration to an NSMD configuration, whereby the advantages of SMD are replaced by the disadvantages of NSMD, however. The choice between SMD and NSMD should, therefore, not have to be decided only on the minimization of the stress influence.

A further possibility for making the soldering connection more stress-resistant is to use larger quantities of solder, which is achieved by enlarging the diameter of the solder balls or by increased application of solder paste. However, the increased quantity of solder, due to increased flowing out of the solder during the soldering process, involves the risk of the formation of short-circuiting bridges, since the required distances cannot be complied with. This may lead to electrical flashovers or connect the solder ball and adjacent soldering pads to one another. This effect occurs particularly in the case of a spatially demanding or asymmetrical arrangement of the soldering connections.

Optimization of the material selection, the development of new adapted materials, optimization of the pad dimensions on the substrate and the second substrate or changes in the construction of the housing that is to be applied later (adaptation of the substrate, housing and chip thickness) are also measures for reducing the stress influence, although they entail considerable outlay.

### SUMMARY OF THE INVENTION

One aspect of the invention is, therefore, to specify a substrate that increases the reliability of soldering connections particularly in the case of ball grid arrays by reducing in a targeted manner the risk of soldering connections breaking away on account of normal and shear stress acting thereon.

In a first possibility, the advantages are achieved by virtue of the fact that a soldering pad is provided with holding means for the solder balls in such a way that, within the top side area of the soldering pad, a depression is introduced in the direction of the substrate or an elevation rising above the surface is applied.

The solder ball, after its application on the soldering pad, will penetrate into the depression or enclose the elevation on the soldering pad. In any event the patterning of the soldering pad creates additional positively locking connections between the solder ball and the soldering pad, which is able to take up shear forces or tensile stresses, so that this makes it more difficult for the solder ball to break away from the soldering pad. These additional positively locking connections can be set, if appropriate individually, to the expected mechanical stress that will act on the soldering connection. The stress may also be determined by means of suitable simulation methods, e.g., by means of finite element simulation (FEM).

In one favorable refinement of the invention, it is provided in this respect that the depression is introduced to a depth, which is less than the height of the side areas. The height of the side areas is usually determined by the material thickness of the metal layer of which the soldering pad is composed. If the depression is smaller than the height, then this means that below the depression there is still a connection between the soldering pad and the substrate, as a result of which this refinement of the solution according to the invention involves both additionally producing a positively locking connection and avoiding reducing the connection between the contact pad and the substrate surface.

In another refinement of the invention, it is provided that the depression is introduced to a depth that is equal to the height of the side areas, the depression being introduced as far as the substrate surface lying below the soldering pad and the substrate surface being uncovered in the region of the depression. Such a solution may be employed in the case of the soldering pads in which the soldering pad exhibits a sufficient adhesion to the substrate. In this case, it is expedient to completely remove the soldering pad in the region of the depression since this makes it possible to achieve a very large positively locking connection.

As an alternative to this, the depression may also be introduced to a depth such that its depth is greater than the height of the side areas. As a result, the depression extends into the substrate material. The solder ball will pour into the depression when it is applied, and so an additional mechanical connection between the soldering pad and the substrate arises via the solder ball itself. Moreover, such a depth affords a maximum resistance to a lateral stress.

In a further refinement of the invention, it is provided that corners that are formed by the depression are rounded. Since the corners are in contact with the solder ball, rounded corners prevent the occurrence of stress spikes and in the process increase the strength between soldering pad and solder ball.

In principle, it is possible for the depression to be effected in multipartite fashion or for a plurality of depressions to be introduced. In particular, it has been found to be expedient for a plurality of depressions to be introduced, this being done such that the soldering pad has, in plan view, the form of an annulus enclosing a cross.

A refinement of this type produces a very large number of areas that are effective in different directions and can thus take up transverse forces.

In the case of this particular refinement, too, it is advantageous that the corners within the cross and between the cross and the annulus are rounded. In this case, too, such rounded corners prevent the occurrence of stress spikes and in the process increase the strength between soldering pad and solder ball.

An enlargement of the connection area and thus a stabilization of the soldering connection with respect to mechanical stress are possible also by means of a vertical segmentation of the soldering pad in addition to the horizontal segmentation. Such a vertical segmentation is achieved by introducing depressions patterned in terrace-like fashion into the soldering pad or applying elevations patterned in terrace-like fashion to the soldering pad. This terrace-like construction has at least two gradations in this case, that is to say three terrace planes, it not being necessary for the terrace planes to lie parallel to the substrate surface or for the gradation to have to be distributed uniformly over the entire height of the soldering pad. They may be adapted in terms of their extent and their direction to the loading determined if appropriate by simulation.

By way of example, the deepest terrace plane of a patterned depression may also be at a distance from the substrate surface, which is the case when the depth of the depression is less than the height of the side area of the soldering pad. This embodiment is employed in such cases if, in accordance with the expected loading, the adhesion of the soldering pad on the substrate has to be accorded greater weight.

Furthermore, it is also possible to combine the horizontal segmentation with the vertical segmentation, as a result of which the reliability of the soldering connection with respect to stress loading can be improved further. The combination of the segmentations is effected by virtue of the depression or elevation patterned in terrace-like fashion being subdivided by one or else a plurality of further, groove-like depressions.

In another refinement of the invention, it is provided that the connecting location between conductor track and soldering pad lies on a virtual first line, which proceeds from the center point of the soldering pad, and the first line lies either parallel to a virtual second line, which runs between the center point of the soldering pad and a neutral point, to which the loading forces running parallel to the substrate surface are directed, or perpendicular thereto. With this configuration, the arrangement of the conductor track in the manner according to embodiments of the invention additionally accepts forces, in particular forces that occur in the direction of the neutral point or perpendicular thereto. This results in an additional support of a soldering pad on the substrate and, consequently, an increase in reliability.

The neutral point will very often be found in the center point of the substrate. Consequently, a further refinement provides for the second line to run between the center point of the soldering pad and the center point of the substrate.

In order to further increase the support of the soldering pad, it is provided that at least one holding strip is connected to the soldering pad, which holding strip has the form of a conductor track and ends at a distance from the soldering pad, and the connecting location of the holding strip to the soldering pad satisfies the same condition as a connecting location of the conductor track to the soldering pad.

For uniform force distribution, a further refinement provides for an even number of conductor tracks and holding strips to be arranged central-symmetrically with respect to the center point of the soldering pad.

One refinement of the invention also provides for a holding strip to be formed as a redundant conductor track by being connected to the conductor track by means of an electrically conductive connection. Even in the case where the soldering pad is detached and the connection between the soldering pad and the conductor track breaks away, the electrical connection is performed by the redundant connection, so that the fault is thus eliminated.

Another possibility for the way in which the advantages are achieved according to embodiments of the invention consists in the fact that the connecting location between conductor track and soldering pad lies on a virtual first line, which proceeds from the center point of the soldering pad. This first line for its part lies either parallel to a virtual second line, which runs between the center point of the soldering pad and a neutral point, to which the loading forces running parallel to the substrate surface are directed, or perpendicular thereto. The neutral point is that point on the substrate to which all displacements run, and at which itself, therefore no displacement or shear forces occur. This solution, according to embodiments of the invention, represents the solution described above as a particular refinement of the first solution according to embodiments of the invention as an independent solution.

The neutral point usually lies in the center of the substrate, so that one advantageous inventive refinement provides for the second line to run between the center point of the soldering pad and the center point of the substrate.

What is achieved by this solution according to embodiments of the invention is that, in principle, the conductor tracks have an orientation directed at increasing the strength. The orientation of the conductor tracks has not afforded a crucial role heretofore. Configurations of this type are directed in particular at the refinement of NSMD. In this case, the pad is mechanically stabilized by the conductor track itself. The conductor track is then covered at a distance in the case of an NSMD configuration once again with soldering resist which, for its part, generates a mechanical strength with respect to the conductor track.

By means of this refinement, particularly in the case of NSMD configurations of the substrate, the substrate is prevented from being torn out from the surface.

In a particularly expedient manner, it is provided in this case that at least one holding strip is connected to the soldering pad, the holding strip having the form of a conductor track. The holding strip ends at a distance from the soldering pad. In particular, in the case of NSMD configurations, it ends at a distance such that it ends below the soldering resist mask, that is to say is covered by soldering resist itself and is thus additionally held by the soldering resist.

With regard to its connecting location to the soldering pad, the holding strip has to satisfy the same condition as a connecting location of the conductor track to the soldering pad.

In a further refinement of the invention, it is provided that an even number of conductor tracks and holding strips are arranged central-symmetrically with respect to the center point of the soldering pad. Gravitational forces can thus be distributed as uniformly as possible over the holding elements or over the conductor tracks without loading the soldering pad to a greater extent at a preferred location.

Finally, a further refinement provides for a holding strip to be formed as a redundant conductor track. This is done by virtue of it being connected to the conductor track by means of an electrically conductive connection. If, on account of a mechanical defect, the conductor track is indeed actually separated from the soldering pad, something that is made more difficult by the invention, then the holding strip performs the function of the conductor track and the connection to the conductor track is maintained via the electrically conductive connection.

In other embodiments, each region in which a soldering connection is to be produced, the soldering mask has an opening (ball pad area) and a group of pillar- or stay-like elevations (pillars) is arranged on the ball pad area. The term pillar is in this case also intended to include those geometrical structures whose height is greater than or equal to at least an edge length of the plan of the structure.

These pillars extend from the metallized surface of the substrate as far as the plane of the upper area of the soldering mask and are distributed in the ball pad area such that a solder ball to be applied can completely enclose each pillar. The electrical connection of the solder ball to the conductor track is realized in this refinement by virtue of the base area of the ball pad area being metallized and this metallization being in direct electrical contact with the conductor track or being formed by the conductor track itself.

This formation of the soldering contact location between conductor track on the substrate and the solder ball by a group of pillars first of all increases the positively locking connection, as already described above. Secondly, the pillars prevent crack propagation in the foot of the solder ball by virtue of the fact that the growing crack line can be stopped at the pillar. Both effects bring about an increase in the reliability of the soldering connection.

A further increase in the connection area between solder ball and pillars is achieved by a lengthening of the individual pillars by virtue of the fact that the substrate in the region of the ball pad area forms a hollow relative to the surrounding substrate surface.

The configuration of the pillars may assume various forms depending on the size and the effective direction of the stress loading. Likewise, the distribution of the individual pillars on the ball pad area may vary correspondingly, it being possible to evaluate the stress loading on account of the mechanical and thermal test or operating conditions or to determine it by simulation.

### BRIEF DESCRIPTION OF THE DRAWINGS

The invention will be explained in more detail below on the basis of two exemplary embodiments. In the associated drawings:

FIG. 1 shows a plan view of a soldering pad of an SMD-BGA in accordance with a first exemplary embodiment;

FIG. 2 shows a cross section along the line II-II in FIG. 1;

FIG. 3 shows a cross section corresponding to the cross section in accordance with FIG. 2 with an applied solder ball;

FIG. 4 shows a plan view of a solder ball with rounded edges corresponding to the first exemplary embodiment;

FIG. 5 shows a cross section along the line V-V in FIG. 4;

FIG. 6 shows a plan view of a soldering pad of an NSMD-BGA in accordance with a second exemplary embodiment;

FIG. 7 shows a plan view of an NSMD ball grid array in accordance with the second exemplary embodiment;

FIG. 8 shows a cross section along the line VIII-VIII in FIG. 6;

FIG. 9 shows a plan view of a soldering pad of an SMD-BGA with holding strips corresponding to the second exemplary embodiment;

FIG. 10A to FIG. 10D show plan views of different configurations of horizontally, vertically or combined horizontally and vertically segmented soldering pads;

FIG. 11 shows a plan view of a plurality of soldering pads of a BGA package with terraced structures;

FIG. 12A to FIG. 12C show plan views of ball pad areas with differently configured and distributed pillars;

FIG. 13A to FIG. 13C show sectional illustrations of the ball pad areas in accordance with FIG. 12A to 12C; and

FIG. 14A and FIG. 14B show sectional illustrations of the ball pad areas in accordance with FIGS. 13A and 13B with an applied solder ball.

The following list of reference symbols can be used in conjunction with the Figures:
1 Soldering pad 18 Neutral point, center point
2 Conductor track 19 Ball grid array
3 Soldering mask 20 Holding strip
4 Opening 21 Electrically conductive connection
5 Edge of the soldering pad 22 Segments
6 Top side area 23 Gradation
7 Depression 24 Package edge
8 Side area 25 Package corner
9 Substrate surface 26 Central soldering pad
10 Solder ball 27 Ball pad area
11 Cross 28 Pillar
12 Annulus 29 Side area of the substrate
13 Free region 30 Metallization
14 Connecting location 31 Crack line
15 First line 32 Substrate
16 Center point of the soldering pad h Height
17 Second line α Angle

### DETAILED DESCRIPTION OF ILLUSTRATIVE EMBODIMENTS

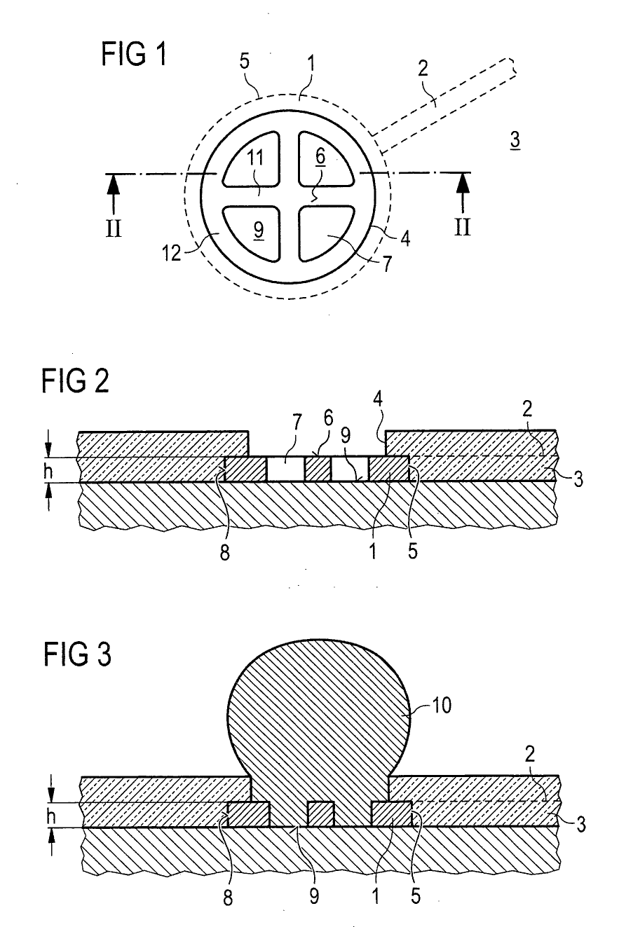

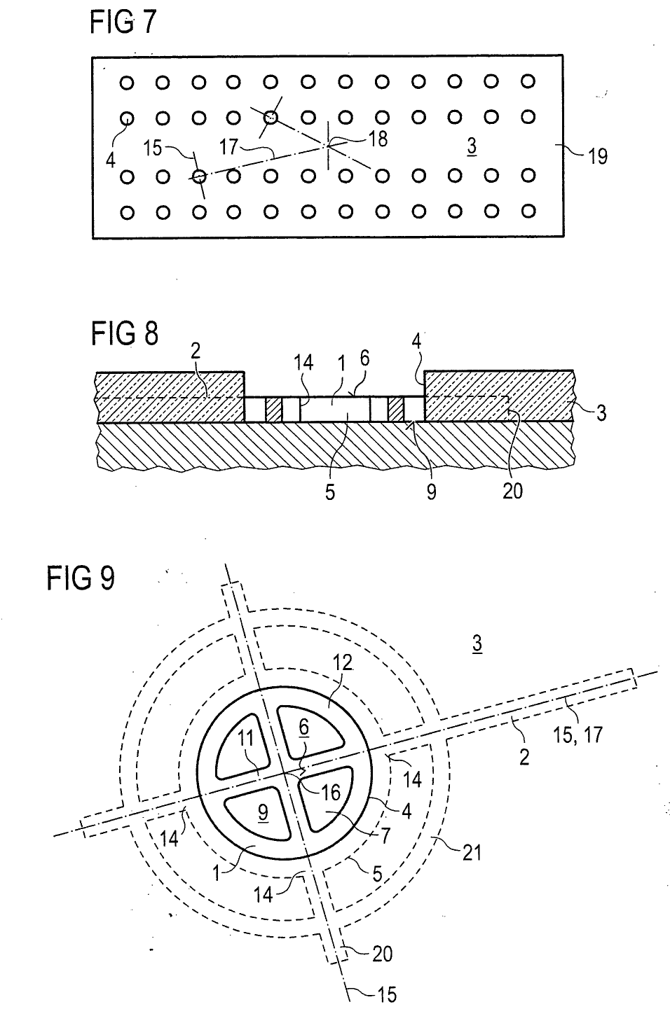

FIG. 1 illustrates a soldering pad 1 connected to a conductor track 2. The soldering pad 1 is realized as part of an SMD ball grid array 19 (see FIG. 7). For this purpose, the soldering mask 3 has an opening 4 having a smaller diameter than the soldering pad 1. Therefore, the soldering mask 3 projects above the edge 5 of the soldering pad 1.

The soldering pad 1 is provided with holding means within its top side area 6, which can be seen from FIG. 2. For this purpose, depressions 7 are introduced into the soldering pad 1 within the top side area 6. In this example, the depressions 7 have a depth that is equal to the height h of the side area 8 of the soldering pad 1. The substrate surface 9 is thus uncovered in the region of the depressions 7.

As illustrated in FIG. 3, a solder ball 10 is inserted into the depressions 7 and thus also forms an additional positively locking connection within the soldering pad 1.

In accordance with FIG. 1, the depressions 7 are introduced such that the soldering pad 1 has, in plan view, the form of an annulus 12 including a cross 11.

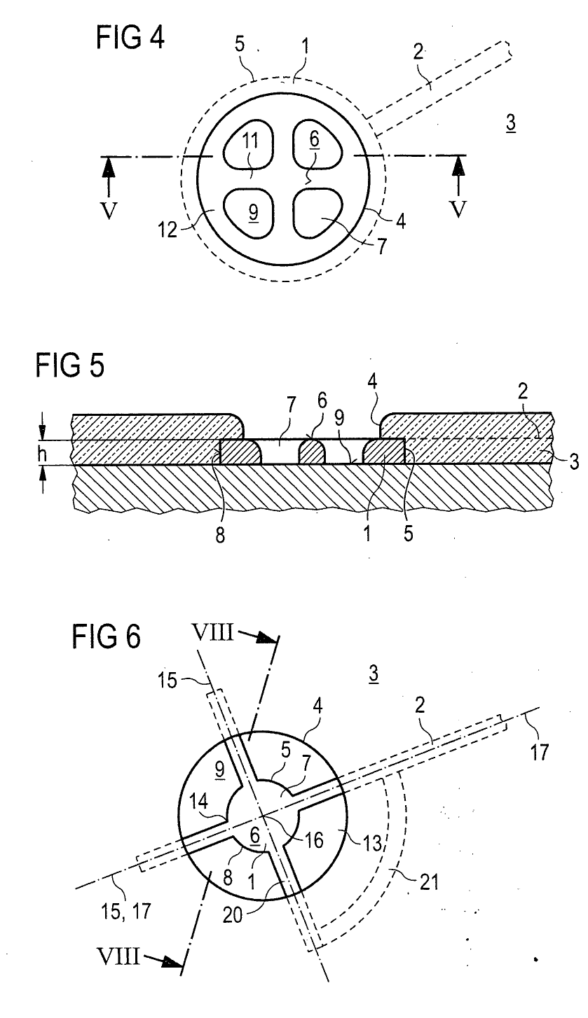

In accordance with FIG. 4, the corners within the cross 11 and between the cross 11 and the annulus 12 are rounded. This serves for further preventing stress on the solder ball 10.

As illustrated in FIG. 5, the corners of the opening 4 and also the edges of the annulus 12 and of the cross 11 in the region of the top side area 6 may also undergo rounding, as a result of which, in this case, the stress loading is further reduced and it is thus additionally possible to prevent the solder ball 10 from experiencing a breakaway in the event of a, in particular, lateral loading.

A gold layer (not specifically illustrated) is usually applied on the soldering pad 1. The adhesion between the solder ball 10 and the soldering pad 1 can be improved further under reduced stress conditions by reducing the gold layer thickness (not specifically illustrated) on the soldering pad 1. This combats the phenomenon where the gold layer enters into the intermetallic phase between soldering pad 1 and solder ball 10 and weakens the connection in the process. The reduction of the gold portion can be effected by means of the invention in parallel with a reduction of the thickness also by means of the area, which has already been effected in the case of the configuration of the soldering pad 1 in the cross-shaped form. This constitutes a further advantage of the cross-shaped soldering pad 1.

FIG. 6 illustrates a plan view of a soldering pad 1 of an NSMD ball grid array 19 (see FIG. 7). In this case, the opening 4 of the soldering mask 3 has a larger diameter than the soldering pad 1. A region 13 around the soldering pad 1 is thus uncovered. The substrate surface 9 can quite generally be seen here. According to embodiments of the invention, in this exemplary embodiment, the connecting location 14 is arranged between the conductor track 2 and the soldering pad 1 on a virtual first line 15. The virtual first line 15 runs from the center point 16 of the soldering pad 1 radially outward. As illustrated in FIG. 7, such a first line 15 coincides with a second virtual line 17, which runs between the center point 16 of the soldering pad 1 and a neutral point 18, which in this example is simultaneously the center point of the ball grid array 19.

The first line 15 thus assumes a special form of parallelism with respect to the second line 17. Holding strips 20 are furthermore arranged, as illustrated in FIG. 6. The holding strips 20 lie as lengthening of the conductor track 2 likewise on a first line 15 lying parallel to the second line 17, or with their line 15 enclosing a perpendicular angle perpendicular to the second line 17. As illustrated in FIG. 6, a holding strip 20 is formed as a redundant conductor track by being connected to the conductor track 2 by means of an electrically conductive connection 21.

As illustrated in FIG. 8, this arrangement now first of all offers additional support for a solder ball 10 (not specifically illustrated). Secondly, the orientation of the conductor track 2 and of the holding strips 20 is suitable for taking up the main loads in the event of thermal or mechanical stresses of the ball grid array 19. Moreover, the holding strips 20 form an additional connection between the soldering pad 1 and the substrate surface 9, thereby further improving the strength of the soldering pad 1 on the substrate 32.

FIG. 9 illustrates a plan view of a soldering pad 1 of an SMD-BGA, which, in addition to the configuration corresponding to the first exemplary embodiment, also has the features of the second exemplary embodiment. In this case, the soldering pad 1 is provided with a plurality of depressions 7, which together form a cross 11 with an annulus 12. An opening 4 in the soldering mask 3 exposes the soldering pad 1.

The soldering pad 1 is connected to a conductor track 2 at the connecting location 14 below the resist mask 3. The connecting location 14 lies on a second line 17 coinciding with the first line 15. The two lines 15 and 17 run from the center point 16 of the soldering pad 1 in the direction of the neutral point 18 according to the illustration in FIG. 7.

The connecting locations 14 between the soldering pad 1 and holding strips 20 likewise lie on a second line 17, which, however, lies perpendicular to the first line 15. The number of holding strips 20 and conductor track 2 together forms an even number, in this case four.

The holding strips 20 are interconnected and connected together with the conductor track 2 via electrically conductive connections 21, which thus constitute redundant connections whose function is manifested if the conductor track 2 actually breaks away at its connecting location 14 to the soldering pad 1. The electrically conductive connections 21 then perform the bridging of the interruption.

Overall, the conductor track 2, the holding strips 20 and the electrically conductive connection 21 in particular below the resist mask 3 form a holding structure that holds the soldering pad 1 securely on the substrate surface 9. The solder ball 10, for its part, is secured on the soldering pad 1 by the depressions 7, with the result that overall it is possible to obtain a very secure configuration of a ball grid array 19 configured from a plurality of such soldering pads 1.

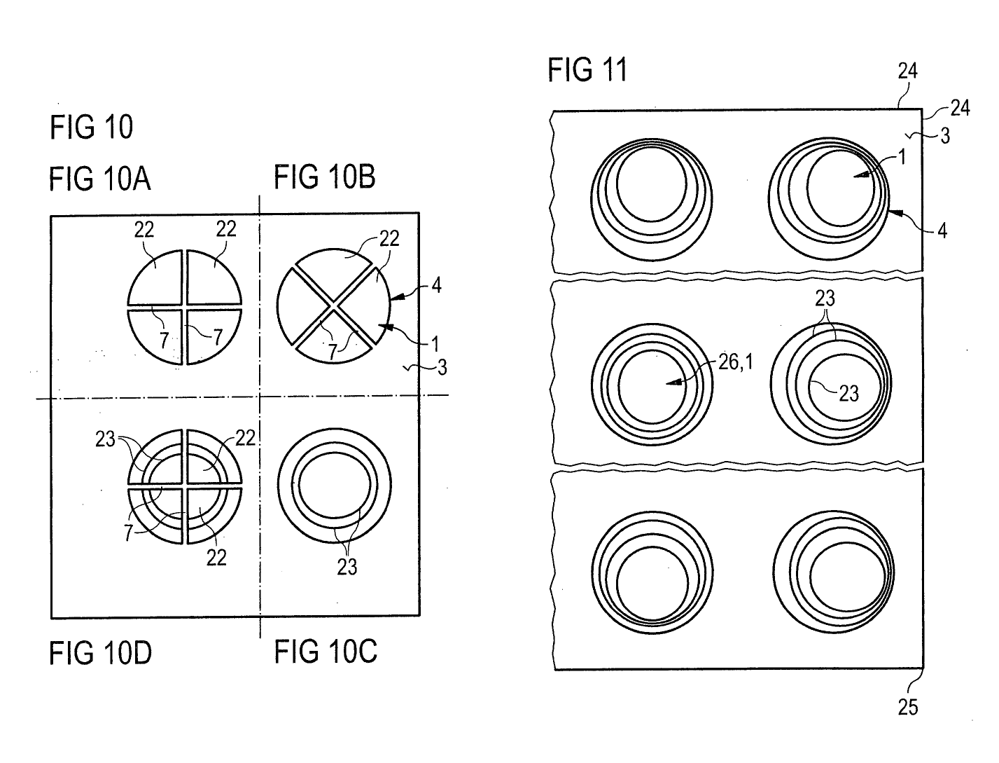

The soldering pads 1 that can be seen in the openings 4 in the soldering mask 3 in accordance with FIGS. 10A to 10D have a wide variety of segmentations. Thus, the soldering pads 1 of FIGS. 10A and 10B are subdivided by four radial groove-type depressions 7, which are in each case arranged at an angle of 90° with respect to one another, horizontally into four segments 22 of equal size, which are separated from one another by the groove-type depression 7.

The soldering pad 1 of FIG. 10C, by contrast, is vertically segmented by virtue of two coaxial gradations 23 each having a decreasing diameter being arranged in the soldering pad 1. A combination of the horizontal segmentation in accordance with FIG. 10A and the vertical segmentation in accordance with FIG. 10C is shown in FIG. 10D. In this case, the four groove-type depressions 7 cut through the terrace-like structure of the soldering pad 1, so that each of the quarter circle segments 22 has the terrace structure.

An adaptation of the circular soldering pad 1 structures of a BGA package to the loading on the soldering connection is illustrated using the example of vertical segmentation in FIG. 11. It is thus to be expected that the mechanical shear and normal loading is greatest at the package edge 24 and at the package corners 25 on account of the curvature behavior based for example on the differences in the coefficients of linear expansion of the connected materials, if the gradient of the gradation 23 was chosen to be greatest toward the package corners 25 and package edges 24 by virtue of the gradations 23 being very dense there, while they are more prolate in the direction of the substrate center. By contrast, the gradations 23 of a central soldering pad 26 are arranged uniformly and coaxially in all directions.

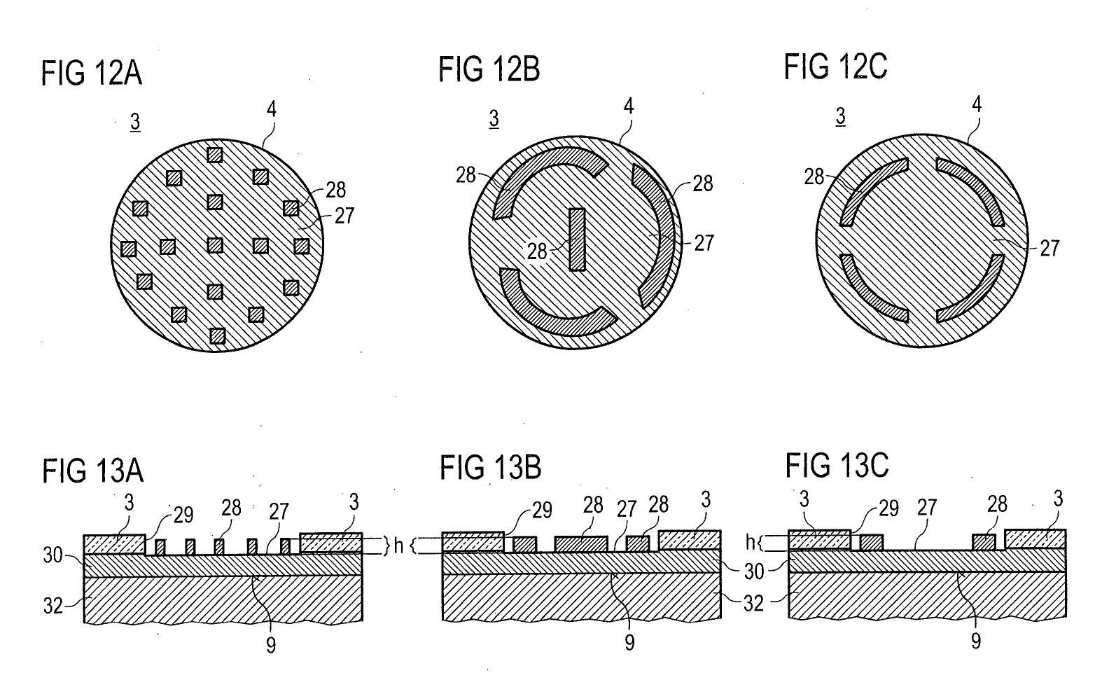

The ball pad areas 27 represented in FIGS. 12A to 12C and the associated sectional illustrations of FIGS. 13A to 13C have differently shaped and differently arranged pillars 28. In all three examples illustrated, their height h is always slightly smaller than the height h of the side area 8 of the soldering mask 3, which delimits the ball pad areas 27.

The pillars 28 in the two FIGS. 12A and 13A have a rectangular cross 11 section having such edge lengths that are less than or equal to the height h of the pillar 28. The distribution of the pillars 28 on the ball pad area 27 is effected uniformly along the four radial principal axes of the circular area and along a circle, which is at a distance from the outer edge of the ball pad area 27 such that the solder material of a solder ball 10 to be applied can flow completely around the pillars 28 during a liquefaction process.

The base area of the pillars 28 in accordance with FIGS. 12B and 13B has the form of segments 22 of the wall of a hollow cylinder, the curvature of the segments 22 deviating from the curvature of the surrounding side area 8 of the soldering mask 3, by being smaller in the exemplary embodiment illustrated. Three of these segment-like pillars 28 are distributed uniformly in the edge region of the ball pad area 27. A further pillar 28 with a rectangular base area is positioned centrally and with all-around spacing apart from the surrounding segment-like pillars 28.

By contrast, this central pillar 28 is absent in the exemplary embodiment in accordance with FIGS. 12C and 13C. Instead of this, four pillars 28 of identical type in the form of segments 22 of a hollow cylinder are arranged coaxially in the edge region of the ball pad area 27. However, it is not necessary always to arrange four pillars 28, provided that the latter have an edge length of their base area that is greater than their height h. The inventive solution also encompasses further forms and numbers of the pillars 28 to be arranged.

In the embodiment in accordance with FIGS. 12A to 12C and 13A to 13C, the substrate surface 9 is covered with a metallization 30, here with a copper metallization 30, in the region of the ball pad areas 27. The metallization 30 is electrically connected to a conductor track 2 (not specifically illustrated). The pillars 28, which are composed of copper in this example, are plated on the ball pad area 27. It is also possible to use other materials or to attach the pillars 28, provided that these materials and connections to the substrate 32 are suitable for bringing about the above-described required positively locking connection to the solder ball 10 and for preventing the crack propagation in the solder ball 10.

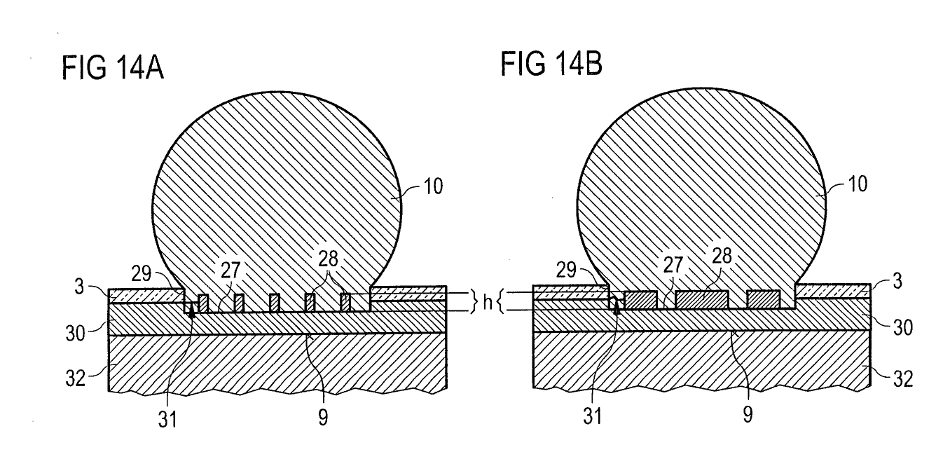

FIG. 14A and FIG. 14B in each case show a substrate 32 according to the invention, on the ball pad area 27 of which a solder ball 10 is applied. A group of pillars 28 having the form in accordance with FIG. 12A, by way of example, is arranged in a manner distributed uniformly on the ball pad area 27 in accordance with FIG. 14A. The pillars 28 in FIG. 14B correspond for example to the configuration and distribution in FIG. 12B. In both FIGS. 14A and 14B, the metallization 30 is lowered in the region of the ball pad areas 27, so that the pillars 28 have a height h that is higher than the side area 8 of the soldering mask 3, and nevertheless again end below the surface of the soldering mask 3. In each case proceeding from the side area 8 of the soldering mask 3, a crack line 31 runs in the solder ball 10, and ends at the nearest pillar 28.

What is claimed is:

1. A substrate for producing a soldering connection to a second substrate, the substrate comprising:
soldering pads distributed on a substrate surface, each soldering pad having a top side area and side areas, each soldering pad including a structure in which solder balls can be held in such a way that, within the top side area of the soldering pad, a depression is introduced in the direction of the substrate or an elevation rising above the top side area is applied;
a plurality of conductor tracks, each soldering pad being electrically connected to a conductor track; and
a soldering mask overlying the substrate surface and including openings in the region of the soldering pads.

2. The substrate as claimed in claim 1, wherein the depression is introduced to a depth that is less than the height of the side areas.

3. The substrate as claimed in claim 1, wherein the depression is introduced to a depth that is equal to the height of the side areas, the depression being introduced as far as the substrate surface lying below the soldering pad and the substrate surface being uncovered in the region of the depression.

4. The substrate as claimed in claim 1, wherein the depression is introduced to a depth that is greater than the height of the side areas, in such a way that the depression extends into a substrate material.

5. The substrate as claimed in claim 1, wherein corners formed by the depression are rounded.

6. The substrate as claimed in claim 1, wherein a plurality of depressions are introduced, the soldering pad having, in plan view, the form of an annulus including a cross.

7. The substrate as claimed in claim 6, wherein corners within the cross and between the cross and the annulus are rounded.

8. The substrate as claimed in claim 1, wherein the soldering pad structure comprises a multilevel hollow or a multilevel bump with at least two gradations.

9. The substrate as claimed in claim 8, wherein the soldering pad structure comprises a multilevel hollow and wherein the multilevel hollow is introduced to a depth that is less than the height of the side areas.

10. The substrate as claimed in claim 8, wherein the multilevel hollow or the multilevel bump is partitioned by a further, groove-like hollow.

11. The substrate as claimed in claim 8, wherein corners formed by the depression are rounded.

12. The substrate as claimed in claim 8, wherein the solder mask exposes several soldering pads and the depth gradient of the multilevel hollow or the height gradient of the multilevel bump of an individual soldering pad is arranged and/or dimensioned in accordance with direction and amount of the loading of the individual solder ball.

13. The substrate as claimed in claim 1, wherein a location where the conductor track and the soldering pad are connected lies on a virtual first line, which proceeds from a center point of the soldering pad, and said virtual first line lies either parallel or perpendicular to a virtual second line, which runs between the center point of the soldering pad and a neutral point, to which the loading forces running parallel to the substrate surface are directed.

14. The substrate as claimed in claim 13, wherein at least one holding strip is connected to the soldering pad, said holding strip having the form of a conductor track and ending at a distance from the soldering pad, wherein a connecting location of the holding strip to the soldering pad satisfies the same condition as a connecting location of the conductor track to the soldering pad.

15. The substrate as claimed in claim 14, wherein an even number of conductor tracks and holding strips are arranged central-symmetrically with respect to the center point of the soldering pad.

16. The substrate as claimed in claim 14, wherein a holding strip is formed as a redundant conductor track by being connected to the conductor track by means of an electrically conductive connection.

17. The substrate as claimed in claim 1, wherein a connection location between the conductor track and the soldering pad lies on a virtual first line, which proceeds from the center point of the soldering pad, and wherein said virtual first line lies either parallel to a virtual second line, which runs between the center point of the soldering pad and the center point of the substrate, or perpendicular thereto.

18. The substrate as claimed in claim 17, wherein at least one holding strip is connected to the soldering pad, the holding strip having the form of a conductor track and ending at a distance from the soldering pad, wherein a connecting location of the holding strip to the soldering pad satisfies the same condition as a connecting location of the conductor track to the soldering pad.

19. The substrate as claimed in claim 18, wherein an even number of conductor tracks and holding strips are arranged central-symmetrically with respect to the center point of the soldering pad.

20. The substrate as claimed in claim 18, wherein a holding strip is formed as a redundant conductor track by being connected to the conductor track by means of an electrically conductive connection.

21. A substrate for producing a soldering connection to a second substrate, the substrate comprising:
soldering pads that are distributed on a substrate surface and on which solder balls can be applied, a soldering pad having a top side area and side areas;
a conductor track, a soldering pad being electrically connected to the conductor track; and
a soldering mask overlying the substrate and including openings in the region of the soldering pads;
wherein a connecting location between conductor track and soldering pad lies on a virtual first line, which proceeds from a center point of the soldering pad, and wherein said virtual first line lies either parallel or perpendicular to a virtual second line, which runs between the center point of the soldering pad and a neutral point, to which the loading forces running parallel to the substrate surface are directed.

22. The substrate as claimed in claim 21, wherein at least one holding strip is connected to the soldering pad, which holding strip has the form of a conductor track and ends at a distance from the soldering pad, wherein a connecting location of the holding strip to the soldering pad satisfies the same condition as the connecting location of the conductor track to the soldering pad.

23. The substrate as claimed in claim 22, wherein an even number of conductor tracks and holding strips are arranged central-symmetrically with respect to the center point of the soldering pad.

24. The substrate as claimed in claim 22, wherein a holding strip is formed as a redundant conductor track by being connected to the conductor track by means of an electrically conductive connection.

25. A substrate for producing a soldering connection to a second substrate, the substrate comprising:
soldering pads that are distributed on a substrate surface and on which solder balls can be applied, a soldering pad having a top side area and side areas and being connected to a conductor track; and
a soldering mask with openings in the region of the soldering pads being applied to the substrate;
wherein a connecting location between conductor track and soldering pad lies on a virtual first line, which proceeds from a center point of the soldering pad, and the virtual first line lies either parallel or perpendicular to a virtual second line, which runs between the center point of the soldering pad and a center point of the substrate.

26. The substrate as claimed in claim 25, wherein at least one holding strip is connected to the soldering pad, the holding strip having the form of a conductor track and ends at a distance from the soldering pad, wherein a connecting location of the holding strip to the soldering pad satisfies a same condition as the connecting location of the conductor track to the soldering pad.

27. The substrate as claimed in claim 26, wherein an even number of conductor tracks and holding strips are arranged central-symmetrically with respect to the center point of the soldering pad.

28. The substrate as claimed in claim 26, wherein the holding strip is formed as a redundant conductor track by being connected to the conductor track by means of an electrically conductive connection.

29. A substrate for producing a soldering connection to a second substrate, the substrate comprising:
a solder mask overlying a top substrate surface, the solder mask having an opening exposing a ball pad area;
a conductor track on the top substrate surface electrically coupled to a laminar metallization extending on the ball pad area; and
a group of soldering pillars distributedly overlying the ball pad area, the soldering pillars extending from the top substrate surface substantially to a level with or under a top surface of the solder mask, each soldering pillar being spaced apart from an adjacent pillar and/or a rim of the solder mask opening.

30. The substrate of claim 29, wherein the top substrate surface constitutes a hollow in the range of the ball pad area.

31. The substrate of claim 29, wherein each pillar in the group of soldering pillars has a base of substantially the same shape.

32. The substrate of claim 31, wherein the soldering pillars are regularly distributed in the ball pad area.

33. The substrate of claim 29, wherein the soldering pillars are distributed along a border area of the ball pad area.

34. The substrate of claim 33, wherein the soldering pillars are formed in the shape of a sector of a hollow cylinder.

35. The substrate of claim 29, wherein the solder mask exposes several ball pad areas and the shape and/or the size and/or the density of the soldering pillars of an individual ball pad area are arranged and/or dimensioned in accordance with loading of an individual solder ball.
